(19) United States
(12) Patent Application Publication
(10) Pub. No.: US 2018/0157094 A1
(43) Pub. Date: Jun. 7, 2018

(54) DISPLAY PANEL INCLUDING HEAT DISSIPATING MEMBER AND DISPLAY DEVICE INCLUDING THE SAME

(71) Applicant: Samsung Display Co., Ltd., Yongin-si (KR)

(72) Inventors: Lu Ly LEE, Yongin-si (KR); Jae Sang LEE, Yongin-si (KR); Seong Sik CHOI, Yongin-si (KR)

(21) Appl. No.: 15/828,531

(22) Filed: Dec. 1, 2017

(30) Foreign Application Priority Data
Dec. 5, 2016 (KR) 10-2016-0164633

(51) Int. Cl. G02F 1/1333; G02F 1/1345; H05K 5/00; H05K 7/20; G02F 1/1335

(52) U.S. Cl. CPC G02F 1/133308; G02F 1/133382; G02F 1/1345; G02F 2001/133314; H05K 7/20409; G02F 1/133602; G02F 2001/13332; H05K 5/0017

(57) ABSTRACT

A display device includes: a display panel including a first substrate including a display area in which a pixel array is disposed and a non-display area at the periphery of the display area, a second substrate opposite to the first substrate, an optical control layer between the first substrate and the second substrate, and at least one heat dissipating metal layer on the first substrate at the non-display area thereof; a light source on a lower surface of the first substrate to correspond to the heat dissipating metal layer; and an upper case disposed to cover the non-display area of the first substrate, a portion of the upper case facing the upper surface of the first substrate at the non-display area thereof to be in direct or indirect contact with the heat dissipating metal layer.

This application claims priority to Korean Patent Application No. 10-2016-0164633, filed on Dec. 5, 2016, and all the benefits accruing therefrom under 35 U.S.C. § 119, the contents of which in their entirety are herein incorporated by reference.

### BACKGROUND

### 1. Field

Embodiments of the present disclosure relates to a display device such as a liquid crystal display that allows heat of a light source to be effectively dissipated to outside the liquid crystal display.

### 2. Description of the Related Art

Display devices such as liquid crystal displays that display characters and images using electro-optical characteristics of an optical control medium such as liquid crystals have excellent color reproduction and low power consumption, and can be manufactured to be thin. Thus, the liquid crystal displays are widely used for televisions, personal computers, potable terminals, and the like.

A liquid crystal display (“LCD”) includes a display panel that displays characters and images with light and a backlight unit that provides light to the display panel.

The display panel includes a substrate having a plurality of pixel electrodes thereon, a substrate having a common electrode thereon, and a liquid crystal layer interposed between the substrates.

The plurality of pixel electrodes are arranged, for example, in a matrix form connected to a plurality of gate lines and a plurality of data lines, thereby constituting a pixel array which generates the characters or images to be displayed.

An electric field between a pixel electrode corresponding to each pixel and the common electrode is controlled according to a driving signal provided to the pixel array, so that the alignment direction of liquid crystals in the liquid crystal layer is controlled according to the optical characteristics thereof. Accordingly, the transmittance of light provided from the backlight unit is adjusted, thereby displaying an image.

### SUMMARY

Embodiments provide a display device such as a liquid crystal display that enables heat of a light source to be effectively dissipated to the outside.

Embodiments also provide a display device such as a liquid crystal display that enables the overall size of a backlight unit to be decreased.

According to an embodiment of the present disclosure, there is provided a display device including: a display panel including a first substrate including a display area in which a pixel array is disposed and a non-display area which is at the periphery of the display area, a second substrate disposed opposite to the first substrate, an optical control layer interposed between the first substrate and the second substrate; and at least one heat dissipating metal layer disposed on an upper surface of the first substrate at the non-display area thereof; a light source attached to a lower surface of the first substrate to correspond to the heat dissipating metal layer; a light guide plate disposed under the display panel such that one side surface of the light guide plate corresponds to the light source; and an upper case disposed to cover the non-display area of the first substrate, a portion of the upper case facing the upper surface of the first substrate at the non-display area thereof, the upper portion being in direct or indirect contact with the heat dissipating metal layer.

The first substrate may include transparent glass.

The display device may further include: a pad unit disposed on the non-display area of the first substrate, the pad unit including a plurality of pads; and a plurality of conductive lines disposed on the non-display area of the first substrate, the plurality of conductive lines electrically connecting the plurality of pads to the pixel array. In a top plan view, the heat dissipating metal layer may be disposed between the plurality of conductive lines. The heat dissipating metal layer may have a discrete pattern shape which is electrically isolated between the plurality of lines.

The display device may further include an insulating layer on the first substrate. The upper case may dispose the insulating layer between the heat dissipating metal layer and the portion of the upper case facing the upper surface of the first substrate. The insulating layer may have a multi-layered structure.

The liquid crystal display may further include a flexible printed circuit board electrically connected to the pad unit to provide driving signals to the pixel array.

The heat dissipating metal layer may include a material selected from gold (Au), silver (Ag), titanium (Ti), tantalum (Ta), tungsten (W), molybdenum (Mo), chromium (Cr), niobium (Nb), aluminum (Al), and copper (Cu), or any alloy of one or more thereof.

The light source may include a printed circuit board, and the printed circuit board may be in thermal contact with the lower surface of the first substrate. The printed circuit board may be attached to the lower surface of the first substrate by a thermally conductive adhesive member.

The display device may further include: an optical sheet interposed between the light guide plate and the first substrate; and a reflective sheet disposed under the light guide plate. The display device may further include a lower case receiving the display panel, the light source and the light guide plate therein, the lower case being coupled to the upper case.

According to one or more embodiment of the present disclosure, since heat generated from the light source is rapidly dissipated to the outside through a relatively short path, degradation of the optical control layer such as a liquid crystal layer or degradation of the light source due to high-temperature heat and failure of components constituting the backlight unit can be reduced or effectively prevented, thereby improving the reliability of a display device such as a liquid crystal display. In addition, since a component for heat dissipation is excluded from a backlight unit of the display device, an overall size of the backlight unit can be decreased as compared with the related art, and accordingly, a total thickness and weight of the display device such as a liquid crystal display can be decreased.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

FIG. 1 is an exploded perspective view illustrating an embodiment of a liquid crystal display according to the invention.

FIG. 2 is an exploded perspective view illustrating an embodiment of a display panel shown in FIG. 1.

FIG. 3 is a top plan view of the display panel shown in FIG. 1, which illustrates an enlarged top plan view of portion A of FIG. 1.

FIG. 4 is a cross-sectional view taken along line B1-B2 of FIG. 3.

FIG. 5 is a cross-sectional view taken along line C1-C2 of FIG. 3.

FIG. 6 is a cross-sectional view illustrating an embodiment of a backlight unit shown in FIG. 1.

FIG. 7 is a cross-sectional view illustrating the liquid crystal display shown in FIG. 1.

### DETAILED DESCRIPTION

Hereinafter, exemplary embodiments of the present disclosure will be described with reference to the accompanying drawings. However, it is to be understood by those skilled in the art that various modifications can be made in the following embodiments of the invention, and the scope of the invention is not limited to the following embodiments.

In the drawing figures, dimensions may be exaggerated for clarity of illustration. Like reference numerals refer to like elements throughout. Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being related to another element such as being “on,” “between” or “connected to” another element, it can be directly on the other element or intervening elements may be present therebetween. In contrast, when an element is referred to as being related to another element such as being “directly on,” “directly between” or “directly connected to” another element, there are no intervening elements present. As used herein, “connected” may refer to a physical, electrical and/or thermal connection between elements.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As sizes and resolutions of display devices are increased, sizes and light amounts of light sources of backlight units within the display devices have been increased. While the size and light amount of a light source are increased, the amount of heat generated by the light sources to be dissipated therefrom to the outside is limited in a confined space within the display device. Hence, due to the confined relatively high-temperature heat, an optical control medium such as liquid crystals are degraded or the lifespan of the light source is shortened. In addition, failures occur in parts or components constituting a backlight unit. Therefore, problems related to the reliability of a display device are caused.

In order to increase the amount of heat dissipated to the outside from a confined space within the display device, the size or number of parts for heat dissipation within the display device should be increased. However, in this case, the size and weight of the display device are increased, and the manufacturing cost of the display device is also increased.

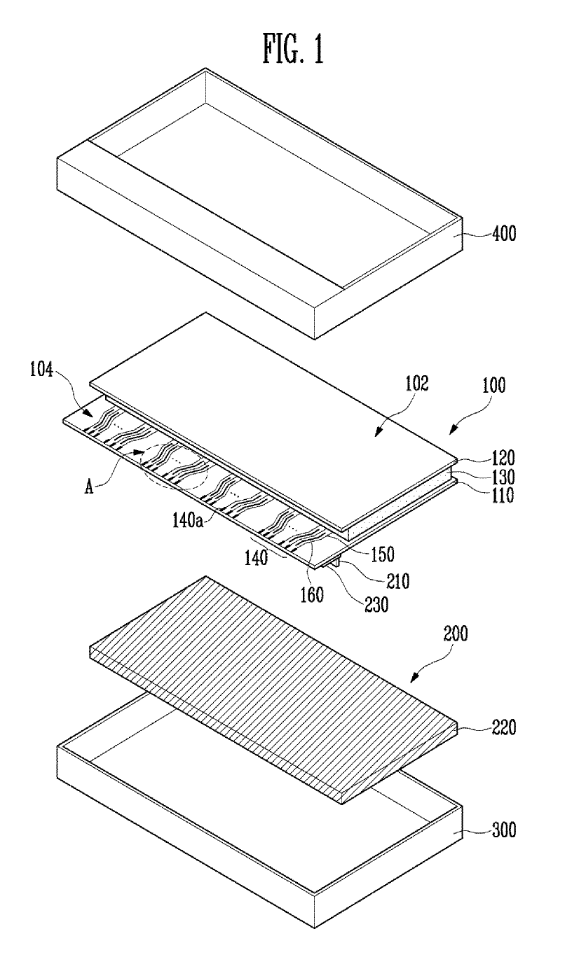

FIG. 1 is an exploded perspective view illustrating an embodiment of a liquid crystal display according to the invention, which schematically illustrates a configuration of the liquid crystal display according to the embodiment.

Referring to FIG. 1, the liquid crystal display as a display device includes a display panel 100 that generates and displays an image with light, a backlight unit 200 that provides the light to the display panel 100, a lower case 300 that receives the display panel 100 and the backlight unit 200 therein, and an upper case 400 that is disposed to cover a portion of the display panel 100 and is coupled to the lower case 300. The liquid crystal display may have a relatively long side lengthwise extended in a first direction and a relatively short side lengthwise extended in a second direction which crosses the first direction. The liquid crystal display and components thereof may be disposed in a plane parallel to that defined by the first and second directions. A third direction which crosses each of the first and second directions defined in a thickness direction of the liquid crystal display and component thereof.

The display panel 100 includes a first (display) substrate 110 including a display area 102 and a non-display area 104 which is at the periphery of the display area 102, a second (display) substrate 120 disposed opposite to the first substrate 100, and an optical control (or transmittance) layer such as a liquid crystal layer 130 interposed between the first substrate 110 and the second substrate 120.

A pixel array may be disposed or formed in the display area 102 of the first substrate 110, such as on a first base substrate thereof. The display panel 100 further includes a pad unit 140 for receiving driving power and/or driving signals, input from outside the display panel 100, a conductive or signal line 150 provided in plurality for electrically connecting the pad unit 140 to the pixel array, and at least one heat dissipating metal layer 160. The first substrate 110 of the display panel 100 may include these elements, such as on the first base substrate thereof, but the invention is not limited thereto.

The pad unit 140 may be provided in plurality, and each pad unit 140 includes a pad 140a provided in plurality. The plurality of pads 140a are electrically connected to the pixel array of the display area 102 through a plurality of lines 150. A flexible printed circuit board (not shown) through which driving power and driving signals provided from the outside the display panel 100 are transmitted thereto, may be electrically connected to the pad unit 140.

The heat dissipating metal layer 160 may be disposed or formed in any of a number of locations of the non-display area 140, such as disposed or formed not to be in electrical contact with the plurality of pads 140a or the plurality of lines 150.

The second substrate 120 may be disposed above the first substrate 110 in a thickness direction of the display (e.g., vertical in FIG. 1). The second substrate 120 is disposed in the display area 102 and a portion of the non-display area 104. An exposed portion of the first substrate 110 may be in or define the non-display area 104.

The first substrate 110 and the second substrate 120 may include a first base substrate and a second base substrate thereof. Such base substrates may be made of a transparent glass. A buffer layer and/or insulating layer may be disposed or formed in the first substrate 110 and the second substrate 120, such as on the base substrate thereof.

The liquid crystal layer 130 is interposed between the first substrate 110 and the second substrate 120, and may be sealed therebetween by a sealant (not shown) between the first substrate 110 and the second substrate 120 along edges thereof.

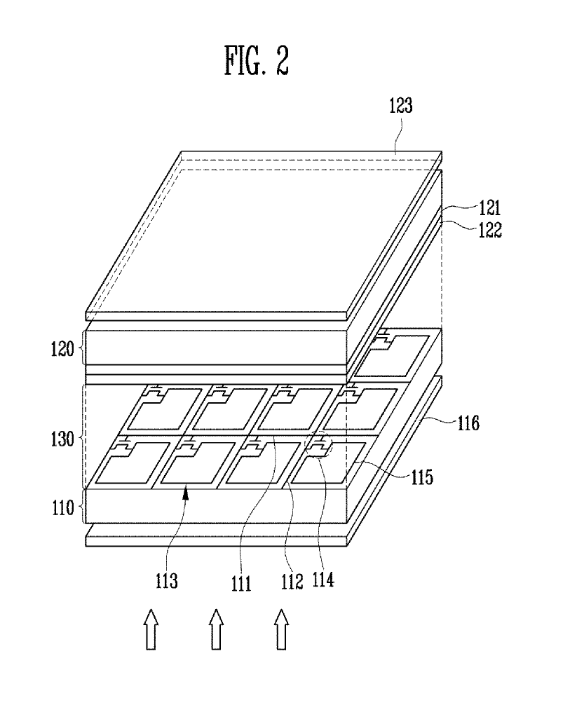

FIG. 2 is an exploded perspective view illustrating an embodiment of the display panel 100 shown in FIG. 1. Only the display area 102 is schematically illustrated for convenience of description.

Referring to FIG. 2, the display panel 100 includes a pixel area 113 provided in plurality at which an image is generated and displayed. A gate line 111 provided in plurality and a data line 112 provided in plurality are each arranged in the display area 102 of the first substrate 110, such as on the base substrate thereof to intersect each other. A pixel electrode 115 is provided in plurality respectively arranged in a matrix form in the pixel areas 113. In one embodiment, the pixel areas 113 may be defined by the gate lines 111 and the data lines 112 intersecting each other, thereby constituting the pixel array, but the invention is not limited thereto.

A switching element such as a thin film transistor 114 for transmitting a signal to the pixel electrode 115 may be disposed or formed in the first substrate 110, such as on the base substrate thereof. The thin film transistor 114 is connected to the pixel electrode 115. The thin film transistor 114 may be disposed at an intersection portion of the gate line 111 and the data line 112, but the invention is not limited thereto.

A color filter 121 and a common electrode 122 are disposed in the display area 102 of the second substrate 120, such as on a base substrate thereof. Polarizing plates 116 and 123 may be disposed on back or outer surfaces of the first substrate 110 and the second substrate 120, respectively.

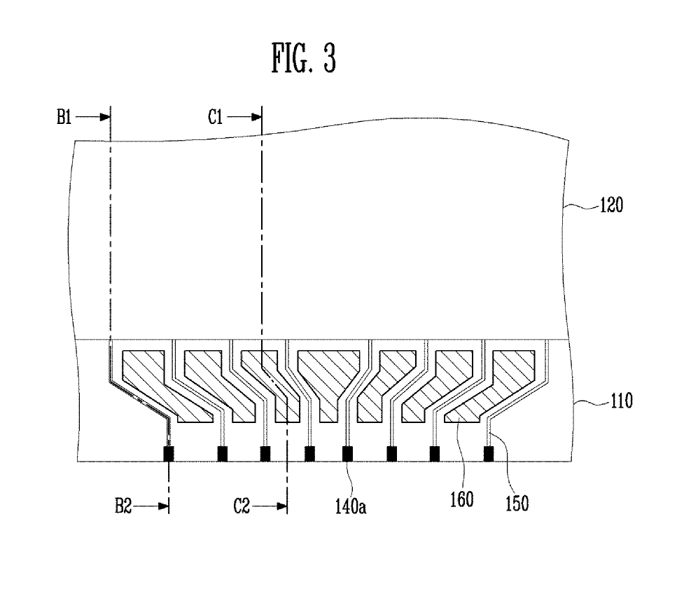

FIG. 3 is a top plan view illustrating the display panel 100 shown in FIG. 1. FIG. 3 illustrates an enlarged top plan view of portion A of FIG. 1 as a portion of the non-display area 104 for convenience of description.

Referring to FIG. 3, the heat dissipating metal layer 160 is disposed or formed in the non-display area 104 of the first substrate 100. The heat dissipating layer 160 is not in electrical contact with the plurality of pads 140a or the plurality of lines 150. The heat dissipating metal layer 160 is disposed or formed to have a maximum planar area in the top plan view, between lines 150 adjacent to each other. The heat dissipating metal layer 160 may have a shape of an independent or discrete thermally conductive pattern which is electrically isolated adjacent to and between the plurality of lines 150. The heat dissipating metal layer 160 may be provided in plurality respectively adjacent to and between the plurality of lines 150.

The heat dissipating metal layer 160 may include or be formed of, as a metal having an excellent heat conduction property. The heat dissipating metal layer 260 may include a material selected from gold (Au), silver (Ag), titanium (Ti), tantalum (Ta), tungsten (W), molybdenum (Mo), chromium (Cr), niobium (Nb), aluminum (Al), and copper (Cu) or any alloy of one or more thereof.

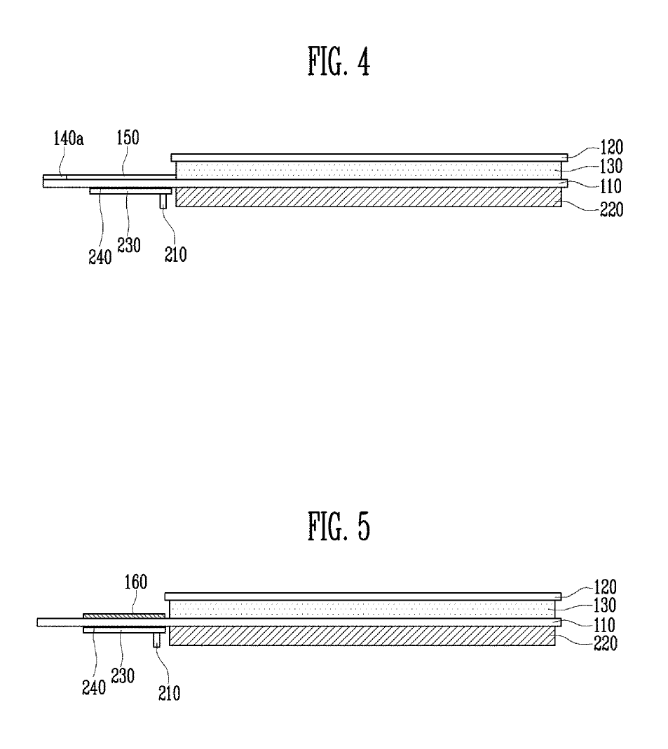

FIG. 4 is a cross-sectional view taken along line B1-B2 of FIG. 3. FIG. 5 is a cross-sectional view taken along line C1-C2 of FIG. 3.

Referring to FIGS. 1, 4 and 5, the backlight unit 200 may include a light source 210 that generates and provides light, and a light guide plate 220 for uniformly guiding light from the light source 210 to the display panel 100.

The light source 210 may be configured as a light emitting diode (“LED”) or the like. A printed circuit board 230 may be connected to the light source 210 to provide power and/or a signal thereto to drive the light source 210. The light source 210 and the printed circuit board 230 may collectively form a light source unit or member. The light source 210 may be provided in plurality on the printed circuit board 230. The printed circuit board 230 may include a driving circuit for driving the light source 210. The printed circuit board 230 may be supplied with power and/or signals from outside thereof. The power and/or the signals may be transmitted through the printed circuit board 230, from outside thereof, and to the light source 210.

Components of the liquid crystal display in an assembled state thereof, such as shown in FIGS. 4 and 5, disposes the light source 210 on the back surface of the first substrate 110 to correspond to the heat dissipating metal layer 160 which is on the front surface of the first substrate 110 opposite to the back surface thereof. In an embodiment, the printed circuit board 230 is attached to the back surface of the first substrate 110, which corresponds to the heat dissipating metal layer 160 on the front surface of the first substrate 110. The printed circuit board 230 may be attached to the first substrate 110 by an adhesive member 240. The light source 210 may be mounted on the printed circuit board 230 to correspond to one side surface of the light guide plate 220. The adhesive member 240 may be an adhesive or double-sided tape including a heat dissipation paste.

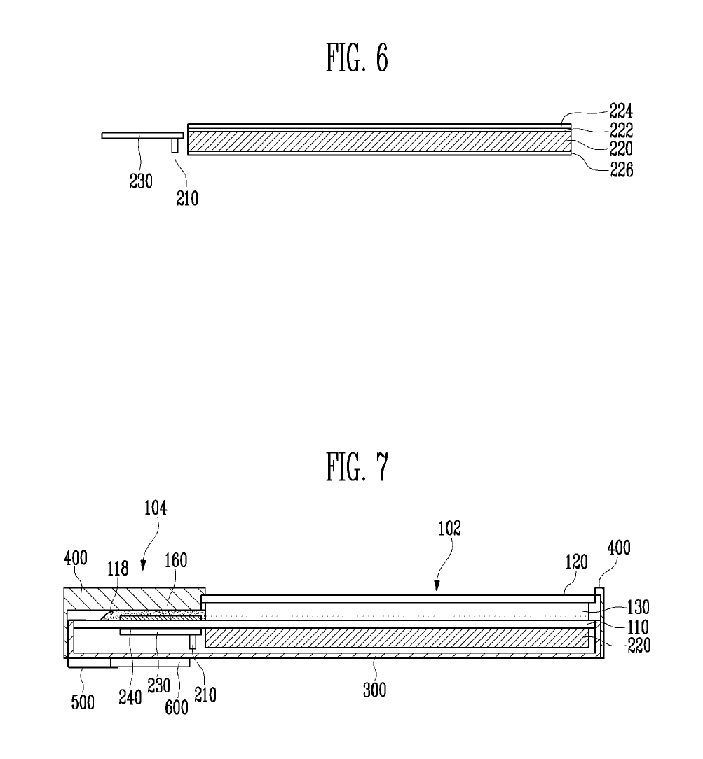

FIG. 6 is a cross-sectional view illustrating an embodiment of the backlight unit 200 shown in FIG. 1. While FIG. 1 omits some components of the backlight unit shown in FIG. 6 for convenience, it will be understood that the backlight unit 200 in FIG. 1 may include the various components illustrated in FIG. 6.

Referring to FIG. 6, components of the backlight assembly 200 in an assembled state thereof, disposes the light guide plate 220 under the display panel 100 such that one side surface of the light guide plate 220 faces the light source 210. The light guide plate 220 may include a light emitting surface facing the display panel 100, a back surface opposite to the light emitting surface, and side surfaces which connect the light emitting surface to the back surface. The side surface at which the light source 210 is disposed, define a light incident surface of the light guide plate 220.

An optical sheet may be disposed on the top of the light guide plate 220. The optical sheet may include a collection of individual sheets such as a diffusion sheet 222 that diffuses light incident thereto from the light guide plate 220 in the direction of the display panel 100, and a prism sheet 224 that improves a vertical (e.g., perpendicular) incident property of the light provided to the display panel 100, by condensing the diffused light.

In addition, a reflective sheet 226 for reflecting light emitted downwards from the light guide plate 220, back to the light guide plate 220, may be disposed under the light guide plate 220.

FIG. 7 is a cross-sectional view illustrating the liquid crystal display shows in FIG. 1. While FIG. 7 omits some components of the backlight unit shown in FIG. 6 for convenience, it will be understood that the components of the backlight unit in FIG. 7 may include the various components illustrated in FIG. 6. In an embodiment, for example, the optical sheet of FIG. 6 may be disposed above the light guide plate 220 in FIG. 7, to be between the light guide plate 220 and the first substrate 110 of the display panel 100.

Referring to FIG. 7, components of the liquid crystal display in an assembled state thereof, disposes the lower case 300 may include a bottom surface portion and a plurality of side walls which extend from the bottom surface. The sidewalls may extend vertically (e.g., perpendicularly) from the bottom surface, but the invention is not limited thereto. A receiving space may be formed inside the lower case 300 by the bottom surface and the plurality of side walls.

The display panel 100 and the backlight unit 200 are received in the receiving space inside the lower case 300. The upper case 400 is disposed on the top of the display panel 100 to cover a portion of the display panel 100. The upper case 400 is disposed at edge portions of the overall display panel 100.

The upper case 400 may include a plurality of side walls respectively corresponding to side surfaces of the display panel 100. An upper portion of the upper case 400 is disposed at the non-display area 104 of the display panel. The upper portion and the side walls of the upper case 400 define an open area corresponding to the display area 102 of the display panel 100 and at which the display area 102 is exposed to outside the liquid crystal display. The side walls may extend vertically (e.g., perpendicularly) from the upper portion or a plane in which the upper portion is disposed. The upper portion may extend from portions of side walls at only three sides of the upper case 400, to define the open area with remaining portions of the side walls.

The upper case 400 may include or be formed of, as a metal having an excellent heat conduction property. The material of the upper case may include one selected from titanium (Ti), tantalum (Ta), tungsten (W), chromium (Cr), aluminum (Al), and copper (Cu), or any alloy of one or more thereof.

The upper case 400 may be disposed on the top of the display panel 100 such that an opening corresponds to the display area 102 of the display panel 100, the upper portion corresponds to the non-display area 104 of the display panel 100, and the plurality of side walls correspond to side surfaces of the display panel 100. At least some of the plurality of side walls of the upper case 400 may be respectively coupled to at least some of the plurality of side walls of the lower case 300. Referring to FIG. 1, where the upper case 400 has four side walls, each of the side walls corresponds to a side surface of the display panel 100 and a portion of these side walls may be coupled to respective side walls of the lower case 300. Where the upper case 400 omits a side wall, such as at a side of the display panel 100 opposite to that at which the light source 210 is disposed, the upper case 400 may include only three side walls to respectively correspond to side walls of the lower case 300.

The lower case 300 and the side surfaces of the display panel 100 may be bonded to each other by a fixing member or adhesive member (not shown). The upper case 400 and the side surfaces of the display panel may be bonded to each other by a fixing member or adhesive member (not shown).

The upper portion of the upper case 400 may be disposed on the top of the display panel 100 to cover the non-display area 104 of the first substrate 110. Hence, the upper portion of the upper case 400 may be disposed adjacent to the heat dissipating metal layer 160 of the first substrate 110. The upper case 400 may be in direct contact with the heat dissipation metal layer 160 with no intervening layers therebetween.

However, when an insulating layer 118 for electrical insulation or protection is disposed or formed on the first substrate 110 including the lines 150 and the heat dissipation metal layer 160, the upper portion of the upper case 400 may be in indirect contact with the heat dissipating metal layer 160 via the insulating layer 118 interposed therebetween. The insulating layer 118 may be disposed or formed, in the display area 102, as an insulating layer or protective layer used in a process of fabricating the pixel array. The insulating layer 118 disposed in the display area 102 may extend outside the display area 102 to define a portion of the insulating layer 118 at the non-display area 104. The insulating layer 118 may include or be formed in a single- or multi-layered structure.

A first side or end of a flexible printed circuit board 500 may be electrically connected to the pad unit 140 of the display panel 100, and a second side or end of the printed circuit board 500 opposite to the first side thereof may be connected to a driving circuit board 600 provided inside or outside of the lower case 300.

The driving circuit board 600 may include a circuit that receives power and signals from outside thereof for displaying an image, and generates driving power and driving signals for driving the pixel array. The driving circuit board 600 may include a driving integrated circuit (“IC”), and the like.

In the liquid crystal display including the heat dissipating metal layer according to one or more embodiment of the present disclosure as described above, heat generated from the light source 210 can be rapidly dissipated to outside the liquid crystal display, through a relatively short path through various components of the liquid crystal display described below.

Heat generated from the light source 210 and heat generated from the printed circuit board 230 may be radiated in all directions, but can be quickly conducted to the first substrate 110 that is most adjacent to the light source 210 and the printed circuit board 230, such as being in direct or indirect thermal contact with the light source 210 and the printed circuit board 230.

The base substrate within the first substrate 110 may include or be made of, for example, glass in the form of a relatively thin film having a thin thickness of about 0.4 millimeter (mm) to about 0.5 mm.

A majority of the heat conducted to the first substrate 110 may also be conducted to the heat dissipating metal layer 160 that is most adjacent to the first substrate 110. The heat conducted to the heat dissipating metal layer 160 may be further conducted to the thermally conductive upper case 400 that is most adjacent to the heat dissipating metal layer 160. The heat conducted to the heat dissipating metal layer 160 may be further conducted to the thermally conductive upper portion of the upper case 400 that is most adjacent to the heat dissipating metal layer 160. The upper case 400 and the upper portion thereof includes or is made of a metal having an excellent heat conduction property. The upper case 400 has a relatively wide planar area at the upper portion thereof. Hence, the upper case 400 including the upper portion thereof enables heat conducted thereto to be dissipated to the outside within a short time.

The heat conducted to the first substrate 110 from the light source 210 is conducted in not only the vertical direction (the thickness direction) of the heat dissipating metal layer 160 but also in the horizontal direction (the length or plane direction) of the heat dissipating metal layer 160. However, due to the heat conduction property of glass, the temperature of the first substrate 110 is rapidly decreased as the distance from the first substrate 110 is increased. Hence, since the pixel array, the liquid crystal layer, the thin film transistor, and the like in the display area 102 are disposed at an increased distance from the light source 210 as compared to the heat dissipating metal layer 160, the pixel array, the liquid crystal layer, the thin film transistor, and the like in the display area 102 are not degraded.

Also, in the liquid crystal display according to one or more embodiment of the present disclosure, the heat dissipating metal layer 160 is included in the display panel 100 as a component for heat dissipation. Hence, a component for heat dissipation may not be included in the backlight unit 200.

Since the component for heat dissipation is excluded from the backlight unit 200, the overall size of the backlight unit 200 can be decreased as compared with the related art, and accordingly, a total thickness and weight of the liquid crystal display including the backlight unit 200 can be decreased.

In the above-described embodiments, the liquid crystal display has been described as an example of a display device in which a light receiving display panel receives light provided from a separate light source. However, the present disclosure may also be applied to any of a number of display devices in which a light receiving display panel receives light provided from a separate light source, such as an electrophoretic display, an electrowetting display, or a MEMS display.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display device comprising:
a display panel which displays an image with light, the display panel including:
a first substrate including a display area in which a pixel array is disposed for displaying the image and a non-display area which is at the periphery of the display area,
a second substrate disposed opposite to the first substrate,
an optical control layer interposed between the first substrate and the second substrate, and
at least one heat dissipating metal layer disposed on an upper surface of the first substrate at the non-display area thereof;
a light source attached to a lower surface of the first substrate opposite to the upper surface thereof, the light source disposed corresponding to the heat dissipating metal layer on the upper surface;
a light guide plate disposed under the display panel, a side surface of the light guide plate corresponding to the light source; and
an upper case disposed to cover the non-display area of the first substrate, a portion of the upper case facing the upper surface of the first substrate at the non-display area thereof, the upper portion being in direct or indirect contact with the heat dissipating metal layer on the upper surface of the first substrate.

2. The display device of claim 1, wherein the first substrate includes transparent glass.

3. The display device of claim 1, further comprising:
a pad unit to which a driving signal is applied to drive the pixel array, the pad unit disposed on the upper surface of the first substrate at the non-display area thereof, the pad unit at the non-display area including a plurality of pads; and
a plurality of conductive lines disposed on the upper surface of the first substrate at the non-display area thereof, the plurality of conductive lines electrically connecting the plurality of pads to the pixel array,
wherein in a top plan view, the heat dissipating metal layer is disposed between conductive lines adjacent to each other at the non-display area of the first substrate.

4. The display device of claim 3, wherein the heat dissipating metal layer has a discrete pattern shape which is electrically isolated between the conductive lines adjacent to each other.

5. The display device of claim 3, further comprising an insulating layer on the upper surface of the first substrate,
wherein in the non-display area of the first substrate, the upper case disposes the insulating layer between the heat dissipating metal layer and the portion of the upper case facing the upper surface of the first substrate.

6. The display device of claim 5, wherein the insulating layer has a multi-layered structure.

7. The display device of claim 3, further comprising a flexible printed circuit board through which the driving signal is provided to the pad unit, the flexible printed circuit board electrically connected to the pad unit.

8. The display device of claim 1, wherein the heat dissipating metal layer includes a material selected from gold (Au), silver (Ag), titanium (Ti), tantalum (Ta), tungsten (W), molybdenum (Mo), chromium (Cr), niobium (Nb), aluminum (Al), and copper (Cu), or any alloy of one or more thereof.

9. The display device of claim 1, wherein the light source includes a printed circuit board, and the printed circuit board is in thermal contact with the lower surface of the first substrate.

10. The display device of claim 9, wherein the printed circuit board is attached to the lower surface of the first substrate by a thermally conductive adhesive member.

11. The display device of claim 1, wherein the upper case includes a metal material.

12. The display device of claim 1, further comprising:
an optical sheet interposed between the light guide plate and the first substrate including the heat dissipating metal layer disposed on the upper surface thereof; and
a reflective sheet disposed under the light guide plate.

13. The display device of claim 1, further comprising a lower case in which is received the display panel including the heat dissipating metal layer, the light source attached to the display panel, and the light guide plate, the lower case being coupled to the upper case.

14. A method of manufacturing a display device, comprising:
providing a display panel which displays an image with light, the display panel including:
a display area at which the image is displayed and a non-display area at which the image is not displayed,
a first substrate facing a second substrate with an optical control layer therebetween, the first and second substrates each including the display area, a portion of the first substrate being exposed from the second substrate to define the non-display area, and
a heat dissipating metal layer disposed on an upper surface of the first substrate, at the non-display area;
providing a light source member which generates the light, the light source member in thermal contact with a lower surface of the first substrate opposite to the upper surface thereof, at a location corresponding to the heat dissipating metal layer on the upper surface; and
disposing an upper case to cover the non-display area of the first substrate, a portion of the upper case at the non-display area disposing the heat dissipating metal layer between the portion of the upper case and the light source.

15. The method of claim 14, wherein
the display panel further includes:
in the display area, a pixel array for displaying the image; and
in the non-display area:
a pad unit to which a driving signal is applied to drive the pixel array, the pad unit disposed on the upper surface of the first substrate, the pad unit including a plurality of pads; and
a plurality of conductive lines disposed on the upper surface of the first substrate, the plurality of conductive lines electrically connecting the plurality of pads to the pixel array, and
in a top plan view, the heat dissipating metal layer is disposed between conductive lines adjacent to each other at the non-display area of the first substrate.

16. The method of claim 15, wherein the heat dissipating metal layer has a discrete pattern shape which is electrically isolated between the conductive lines adjacent to each other.

17. The method of claim 14, wherein the light source member includes:
a light source which generates the light, and
a circuit board on which the light source is mounted,
wherein the circuit board is attached to the lower surface of the first substrate by a thermally conductive adhesive member.
